(19) United States
(12) Patent Application Publication
(10) Pub. No.: US 2022/0410760 A1
(43) Pub. Date: Dec. 29, 2022

(54) METHOD OF ESTIMATING THE REMAINING DRIVING DISTANCE AVAILABLE FROM A CHARGE FOR A POWERED MOBILITY DEVICE

(71) Applicant: PERMOBIL AB, Timrå (SE)

(72) Inventors: Björn WALTHER, Matfors (SE); Mikael ELIASSON, Borlänge (SE); Adam BÄCKMAN, Sörberge (SE)

(21) Appl. No.: 17/783,571

(22) PCT Filed: Dec. 8, 2020
(86) PCT No.: PCT/EP2020/085033

§ 371 Date: Jun. 8, 2022

(30) Foreign Application Priority Data
Dec. 12, 2019 (EP) 19215785.7

(51) Int. Cl. B60L 58/12; B60L 58/16; G01R 31/367; G01R 31/392; G01R 31/3828

(52) U.S. Cl. CPC B60L 58/12; B60L 58/16; G01R 31/367; G01R 31/392; G01R 31/3828; B60L 2260/52

(57) ABSTRACT

A method of estimating the remaining driving distance available from a current charge of a battery of an electrically powered mobility device, wherein the method comprises: a) determining a state of charge of the battery based on a measured battery-related parameter, b) determining a state of health of the battery based on the state of charge, and c) estimating the remaining driving distance that the mobility device can travel with the current charge based on the state of charge and the state of health, wherein step b) involves determining the state of health based on actual consumed ampere hours of the battery.

### TECHNICAL FIELD

The present disclosure generally relates to electrically powered mobility devices.

### BACKGROUND

Electrically powered mobility devices such as wheelchairs comprise an electric motor powered by a battery pack. It facilitates for the users of mobility devices to be aware of how much charge is left in the battery pack at any moment. Thereby better route planning may for example be performed.

There are products on the market which display the remaining charge in the battery pack of wheelchairs. These products are however prone to provide incorrect information about the remaining charge in the battery pack. The battery charge status may for example jump up and down seemingly randomly. This renders existing battery indicators essentially useless.

US2012/256599 A1 discloses a battery management system (BMS) and a method of controlling the same. The BMS includes a reference setup unit configured to set a charge completion value used to calculate a state of health (SOH) of the battery, wherein the battery comprises one or more battery packs each including a plurality of battery cells, and a charge amount calculation unit configured to calculate an amount actually charged in the battery from a first point in time when charging of the battery begins to a second point in time when the battery charging actually reaches the charge completion value. The BMS may further include an SOH calculation unit configured to calculate the SOH of the battery based on a ratio of i) the actual charge amount to ii) a preset charge amount expected to be charged from the first time point to the second time point.

### SUMMARY

An object of the present disclosure is to provide a method which solves, or at least mitigates problems of the prior art.

Other objects are to provide a battery monitoring device, an electrically powered mobility device and a system.

There is hence according to a first aspect of the present disclosure provided a method of estimating the remaining driving distance available from a current charge of a battery of an electrically powered mobility device, wherein the method comprises: a) determining a state of charge of the battery based on a measured battery-related parameter, b) determining a state of health of the battery based on the state of charge, and c) estimating the remaining driving distance that the mobility device can travel with the current charge based on the state of charge and the state of health.

The estimation of the remaining driving distance may thereby be made more accurate. This may be obtained because the state of health of the battery is used for determining the remaining driving distance. The state of health is a measure of the present capacity of the battery in relation to its nominal capacity. The state of health is hence a measure of the health of the battery compared to its nominal capacity. The nominal capacity may for example be the nominal ampere hours of the battery.

With “current charge” is meant the latest, last or most recent charge of the battery. In other words, the current charge is the most recent battery charging occasion, action or event.

A mobility device is a device that aids the movement of individuals with physical impairments. A mobility device may for example be a wheelchair, an electric cart, a scooter or a personal transporter.

The state of charge is a measure of the relative capacity of the battery that has been utilised. The state of health of the battery influences how the state of charge is to be interpreted for the purpose of estimating the remaining driving distance.

The remaining driving distance may be the instantaneous remaining driving distance.

According to one embodiment step b) involves determining the state of health based on actual consumed ampere hours of the battery.

According to one embodiment step b) involves determining the actual consumed ampere hours of the battery based on calculated consumed ampere hours.

Some mobility devices may be provided with an ampere meter configured to calculate the consumed ampere hours based on the battery load. The calculated consumed ampere hours may however not reflect the entire power consumption of the mobility device. The built-in ampere meter available in conventional mobility devices may provide a calculated current consumption based on the motor load, but it may not reflect the entire current consumption of the mobility device, which includes e.g. the current consumption of the user interface and the control system. For such implementations it is beneficial to determine the actual consumed ampere hours instead of using the calculated consumed ampere hours, to obtain a more accurate estimation of the remaining driving distance.

The actual consumed ampere hours is an approximation of the true consumed ampere hours of the entire battery load.

According to one embodiment the determining of the actual consumed ampere hours is further based on a power-on time which is the time the mobility device has been powered on since the current charge and a motor active time which is the time the motors of the mobility device have been active since the current charge.

According to one embodiment the state of health is determined further based on the nominal ampere hours of the battery.

According to one embodiment the state of health is determined based on a ratio between the actual consumed ampere hours and the state of charge times the nominal ampere hours.

According to one embodiment in step c) the remaining driving distance is estimated by multiplying the state of charge with the state of health and with the nominal ampere hours of the battery to obtain a product which is divided by an average power consumption of the battery.

The average power consumption of the battery may be determined by dividing the actual consumed ampere hours with the distance travelled by the mobility device with the current battery charge.

According to one embodiment the battery-related parameter is a battery voltage.

The battery voltage may be measured when the mobility device is turned off. This may be necessary in case the voltage measurement device is located relatively far from the battery, in which case the voltage drop due to the distance will render the voltage measurements unreliable when the mobility device is turned on.

The mobility device may be configured to start to measure the battery voltage after the mobility device has been turned off and the battery voltage exceeds a voltage threshold.

According to one embodiment the battery-related parameter is the number of hours that the battery has been charged to obtain the current charge.

One embodiment comprises filtering the state of health obtained in step b), and using the filtered state of health in step c) to estimate the remaining driving distance. Rapid changes in the estimation of the state of health, which may occur for example due to the influence of ambient temperature, the structure and/or the inclination of the ground surface, and additional weight carried by the mobility device, because of consumed ampere hours being used for determining the state of health, may thereby be compensated for.

There is according to a second aspect of the present disclosure provided a battery monitoring device comprising: processing circuitry, and a storage medium, wherein the storage medium comprises a computer program which when executed by the processing circuitry causes the battery monitoring device to perform the method according to the first aspect.

One embodiment comprises an input device configured to obtain the measured battery-related parameter from an electrically powered mobility device and to send the remaining driving distance to the electrically powered mobility device.

There is according to a third aspect of the present disclosure provided an electrically powered mobility device comprising a battery, a battery parameter measurement unit configured to measure a battery-related parameter of the battery, and a communications unit configured to send the measured battery-related parameter wirelessly to the battery monitoring device according to the second aspect, and to receive the remaining driving distance from the battery monitoring device.

One embodiment comprises a display configured to display the remaining driving distance.

According to one embodiment the electrically powered mobility device is a wheelchair.

There is according to a fourth aspect provided a system comprising: the electrically powered mobility device according to the third aspect, and a battery monitoring device according to the second aspect configured to communicate with the electrically powered mobility device.

The battery monitoring device may for example be a server. The battery monitoring device may form part of a cloud system. The battery monitoring device may be arranged remotely from the electrically powered mobility device.

Generally, all terms used in the claims are to be interpreted according to their ordinary meaning in the technical field, unless explicitly defined otherwise herein. All references to “a/an/the element, apparatus, component, means, etc.” are to be interpreted openly as referring to at least one instance of the element, apparatus, component, means, etc., unless explicitly stated otherwise.

### BRIEF DESCRIPTION OF THE DRAWINGS

The specific embodiments of the inventive concept will now be described, by way of example, with reference to the accompanying drawings, in which:

FIG. 1 schematically shows an example of a system comprising a battery monitoring device and an electrically powered mobility device;

FIG. 2 schematically shows a block diagram of the battery monitoring system in FIG. 1;

FIG. 3 is a schematic block diagram of an example of a mobility device; and

FIG. 4 is a flowchart of a method of estimating the remaining driving distance available from a current charge of a battery of an electrically powered mobility device.

### DETAILED DESCRIPTION

The inventive concept will now be described more fully hereinafter with reference to the accompanying drawings, in which exemplifying embodiments are shown. The inventive concept may, however, be embodied in many different forms and should not be construed as limited to the embodiments set forth herein; rather, these embodiments are provided by way of example so that this disclosure will be thorough and complete, and will fully convey the scope of the inventive concept to those skilled in the art. Like numbers refer to like elements throughout the description.

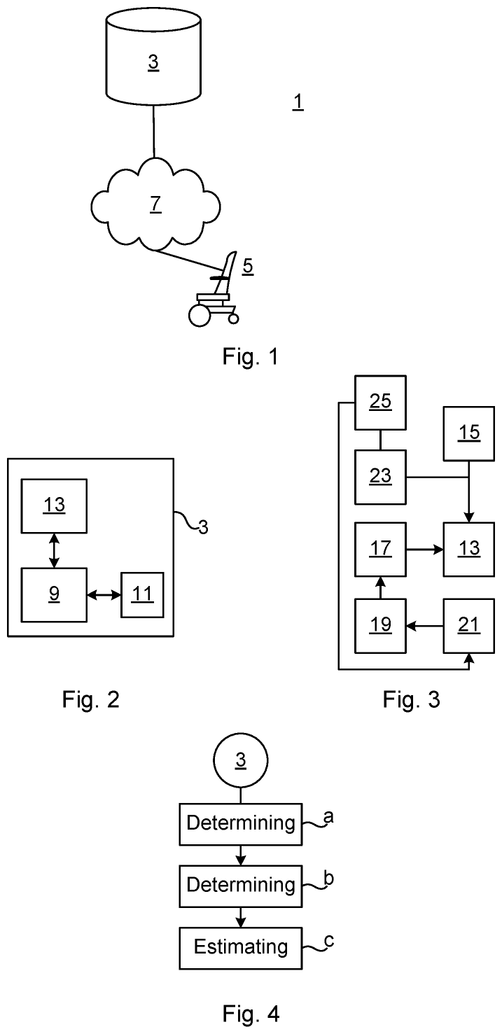

FIG. 1 shows an example of a system 1 including a battery monitoring device 3 and an electrically powered mobility device 5. The electrically powered mobility device 5 comprises an electric motor and a battery configured to power the electric motor.

The battery monitoring device 3 is configured to be communicatively connected to the mobility device 5 by means of a communications network 7. The communications network 7 may comprise an access network, which may be at least partly wireless, and which may include e.g. 3G, 4G, 5G, Wi-Fi or any similar technology, and a service network such as the Internet. The battery monitoring device 3 and the mobility device 5 are in this example configured to communicate wirelessly over the communications network 7.

The mobility device 5 is configured to measure a battery-related parameter of the battery. The battery-related parameter may for example be a battery voltage or the charging time of the battery.

The mobility device 5 is configured to send the measured battery-related parameter to the battery monitoring device 3 via the communications network 7.

The battery monitoring device 3 is configured to receive the measured battery-related parameter from the mobility device 5 and to process the measured battery-related parameter.

The battery monitoring device 3 is configured to estimate the remaining driving distance that the mobility device 5 can travel with the current charge based on the measured battery-related parameter. Further, the battery monitoring device 3 is configured to send the estimated remaining driving distance to the mobility device 5.

The mobility device 5 is configured to present the estimated remaining driving distance to the user. For example, the mobility device 5 may comprise a display configured to display the estimated remaining driving distance.

As an alternative to the above distributed example, the battery monitoring device could form part of the mobility device. The battery monitoring device could hence be mounted to the mobility device.

FIG. 2 schematically shows a block diagram of the battery monitoring device 3. The battery monitoring device 3 comprises processing circuitry 9 and an input device and an output device together denoted by 11. The input device and the output device are configured to communicate with the processing circuitry 9 and with the mobility device 5. Depending on the implementation of the processing circuitry 9, the battery monitoring device 3 may comprise a storage medium ii.

The processing circuitry may for example use any combination of one or more of a suitable central processing unit (CPU), multiprocessor, microcontroller, digital signal processor (DSP), application specific integrated circuit (ASIC), field programmable gate arrays (FPGA) etc., capable of executing any herein disclosed operations concerning the estimation of the remaining driving distance that the mobility device can travel with the current charge.

The storage medium may for example be embodied as a memory, such as a random access memory (RAM), a read-only memory (ROM), an erasable programmable read-only memory (EPROM), or an electrically erasable programmable read-only memory (EEPROM) and more particularly as a non-volatile storage medium of a device in an external memory such as a USB (Universal Serial Bus) memory or a Flash memory, such as a compact

Flash memory.

FIG. 3 shows a block diagram of components of the mobility device 5. The mobility device 5 comprises an electric motor system 13, typically comprising electric motors configured to drive a respective drive wheel, a battery 15, power converters 17, and a control system 19. The battery 15 is configured to power the electric motor system 13. The power converters 17 are configured to control a respective electric motor. The control system 19 is configured to control the power converters 17. The mobility device 5 furthermore comprises a user interface 21 with which the user can interact for controlling the electric motors via the control system 19.

The mobility device 5 comprises a battery parameter measurement unit 23 configured to measure a battery-related parameter of the battery 15. The battery parameter measurement unit 23 may for example comprise a volt meter configured to measure the battery voltage of the battery 15. The battery parameter measurement unit 23 may according to one variation comprise a timer configured to determine the time that that the battery 15 has been charging. The timer may be configured to start counting in case the battery voltage measured by the volt meter exceeds a voltage that the battery 15 is able to provide in operation of the mobility device 5. When the timer has counted to a predetermined number, it gives an indication that the battery 15 is fully charged.

In case the volt meter is located at such a distance from the battery 15 that the volt meter is not able to measure the battery voltage with good precision due to the voltage drop over the electric wiring between the battery 15 and the volt meter, the battery parameter measurement unit 23 may be configured to measure the battery voltage when the mobility device 5 has been turned off.

The mobility device 5 is configured to send the measured battery-related parameter to the battery monitoring device 3. The mobility device 5 comprises a communications unit 25 configured to send the measured battery-related parameter to the battery monitoring device 3 and to receive the remaining driving distance from the battery monitoring device 3.

FIG. 4 shows a flowchart of a method of estimating the remaining driving distance available from a current charge of the battery of the mobility device 5. The method is performed by the battery monitoring device 3.

As previously noted, the battery-related parameter is measured by the mobility device 5 and sent to the battery monitoring device 3.

In a step a) a state of charge of the battery is determined based on the measured battery-related parameter. The measured battery-related parameter may for example be compared with reference values of the battery-related parameter to determine the state of charge. Each reference value may be associated with a certain state of charge.

In case the battery-related parameter is the battery voltage, it can be compared to historical or reference battery voltage levels to determine the state of charge in step a).

In case the battery parameter measurement unit 23 is configured to measure the time of charging, the measured batter-related parameter may be the time of charging. The battery monitoring device 3 may be configured to compare the time of charging with reference times of charging to determine the state of charge.

According to one variation, the battery monitoring device 3 may be configured to obtain a battery temperature and an ambient temperature around the battery. The determining in step a) may in this case further be based on the battery temperature and the ambient temperature. In this case, the determining may involve comparing the battery-related parameter with historical or reference values that are further dependent of the battery temperature and ambient temperature. For example, in case the battery-related parameter is the battery voltage, it can be compared to historical or reference battery voltage levels at the corresponding battery temperature and ambient temperature.

The mobility device may in this case be provided with a temperature sensor configured to detect the battery temperature. The mobility device may be provided with a temperature sensor configured to detect the ambient temperature.

According to one variation, the battery monitoring device 3 may be configured to obtain the ambient temperature around the battery based on a position of the mobility device from a service provider such as Google®.

In a step b) the state of health of the battery is determined based on the state of charge. Step b) may involve determining the state of health based on the actual consumed ampere hours of the battery.

For some mobility devices on the market provided with ampere meters, the ampere meter may not actually measure the consumed current but only provide a calculated current consumption based on the load. Such calculations may also in some cases only take the current consumed by the motors and not those of peripheral devices into account. The calculated current consumption may therefore not exactly correspond to the actual current consumption. The actual consumed ampere hours may be determined based on the calculated current consumption.

The mobility device 5 is in this case configured to calculate the current consumed from the battery 15. The mobility device 5 may for example comprise an ampere meter configured to calculate the consumed current.

Step b) may in this case involve determining the actual consumed ampere hours of the battery based on calculated consumed ampere hours.

The mobility device 5 may be configured to send the calculated consumed ampere hours or the actual consumed ampere hours to the battery monitoring device 3. Alternatively, the mobility device 5 may be configured to send calculated accumulated current and the time that the mobility device 5 has been active to the battery monitoring device 3. The battery monitoring device 3 may in this case be configured to act as an ampere hour counter to determine the actual consumed ampere hours based on the calculated accumulated current and the time. The calculated accumulated current multiplied by the time that the mobility device 5 has been active to the battery monitoring device 3 form the calculated consumed ampere hours.

In case of dealing with calculated consumed ampere hours, the actual consumed ampere hours may in step b) be determined further based on a power-on time ton which is the time the mobility device has been powered on since the current charge, and based on the motor active time t_{motoractive}, which is the time the electric motors of the mobility device 5 have been active under the current charge. Specifically, the actual consumed ampere hours Ihᵣₑₐₗ may be determined by means of equation (1) below.

Ihᵣₑₐₗ=C*Ih_{calc}+D*t_{motoractive}+E*t_{on tm (}1)

where C, D and E are constants which can be determined by curve-fitting and Ih_{calc} is the calculated consumed ampere hours.

The mobility device 5 may be configured to send the power-on time tₒₙ and the motor active time t_{motoractive} to the battery monitoring device 3.

In case the mobility device 5 is configured to measure the actual consumed ampere hours, the measured actual consumed ampere hours may be used as the actual consumed ampere hours in step b).

In step b) the determining of the state of health may further involve determining a ratio between the actual consumed ampere hours and the nominal ampere hours of the battery 15. The numerator of the ratio i.e. the nominal ampere hours of the battery 15 may be scaled using the state of charge at start, i.e. at full charge, minus the present state of charge. Thus, the state of health, SOH, may be determined by equation (2) below.

$$SOH = \frac{I {h}_{r e a l}}{( S O {C}_{start} - SO {C}_{p resent} ) I {h}_{batterycapacity}} \qquad ( 2 )$$

where Ih_{batterycapacity} is the nominal ampere hours of the battery 15, SOCₛₜₐᵣₜ is the state of charge at start and SOCₚᵣₑₛₑₙₜ is the present state of charge determined in step a).

In a step c) the remaining driving distance that the mobility device can travel with the current charge is estimated based on the state of charge and the state of health.

According to one example, the state of health obtained e.g. from equation (2) may be filtered before step c). Step c) may in this case involve estimating the remaining driving distance based on the state of charge and the filtered state of health.

The filtered state of health may for example be determined by the sum of a weighted state of health as determined in the current iteration of the method and a weighted filtered state of health as determined in a previous iteration of the method. The filtered state of health SOHfiltered may for example be determined by SOHfiltered=(SOH/n)+(SOHoldfiltered*(n−1))/n, where SOH is the state of health determined in the current iteration of the method, and SOHoldfiltered is the filtered state of health determined in a previous iteration of the method, for example the last iteration before the current one. n is an integer for example in the range 5-20. According to one example n=10.

The remaining driving distance may be estimated by multiplying the state of charge with the state of health and with the nominal ampere hours of the battery 15 to obtain a product P=SOH*SOCₚᵣₑₛₑₙₜ*Ih_{batterycapacity}, which is divided by the average power consumption e of the battery 15. The remaining driving distance d_{available} may hence be estimated by means of equation (3).

$${d}_{a v a i l a b l e} = \frac{S O {C}_{p resent} \cdot SOH \cdot {Ih}_{batterycapacity}}{e} \qquad ( 3 )$$

The average power consumption e of the battery 15 may be determined by dividing the actual consumed ampere hours Iₕᵣₑₐₗ with the distance travelled by the mobility device 5 with the current charge. The distance travelled with the current charge may be sent to the battery monitoring device 3. The average power consumption e is in the present example expressed in units Ah/m.

As mentioned earlier, the battery monitoring device 3 is configured to send the remaining driving distance d_{available} to the mobility device 5. The mobility device 5 is configured to present the remaining driving distance to the user via the user interface 21. For example, the user interface 21 may comprise a display configured to display the remaining driving distance.

By means of the remaining driving distance presented to the user, the user of the mobility device 5 may obtain more accurate information regarding how far the mobility device 5 at essentially any given moment is able to travel with the charge available in the battery 15. The user is thereby able to perform route planning more accurately than what has previously been possible.

According to one variation, the battery monitoring system may be configured to detect if the state of charge has dropped below for example 40% or below 30% in combination with mobility device having been turned off for a plurality of days such as at least 3 days, at least 4 days or at least 5 days. In this case, the battery monitoring system may be configured to provide an alarm. The alarm may be triggered again when the state of charge drops below for example 15%, 10% and 5%. The alarm may be provided to the mobility device.

The inventive concept has mainly been described above with reference to a few examples. However, as is readily appreciated by a person skilled in the art, other embodiments than the ones disclosed above are equally possible within the scope of the inventive concept, as defined by the appended claims.

1. A method of estimating the remaining driving distance available from a current charge of a battery (15) of an electrically powered mobility device (5), wherein the method comprises:
a) determining a state of charge of the battery (15) based on a measured battery-related parameter,
b) determining a state of health of the battery (15) based on the state of charge, and
c) estimating the remaining driving distance that the mobility device (5) can travel with the current charge based on the state of charge and the state of health,
wherein step b) involves determining the state of health based on actual consumed ampere hours from the battery (15),
wherein step b) involves determining the actual consumed ampere hours of the battery based on calculated consumed ampere hours from an ampere meter of the mobility device, configured to calculate the consumed current.

2. The method as claimed in claim 1, wherein the determining of the actual consumed ampere hours is further based on a power-on time which is the time the mobility device (15) has been powered on since the current charge and a motor active time which is the time the motors of the mobility device (15) have been active since the current charge.

3. The method as claimed in claim 1, wherein the state of health is determined further based on the nominal ampere hours of the battery.

4. The method as claimed in claim 3, wherein the state of health is determined based on a ratio between the actual consumed ampere hours and a state of charge at full charge minus the state of charge determined in step a) times the nominal ampere hours.

5. The method as claimed in claim 1, wherein in step c) the remaining driving distance is estimated by multiplying the state of charge with the state of health and with the nominal ampere hours of the battery (15) to obtain a product which is divided by an average power consumption of the battery (15).

6. The method as claimed in claim 1, wherein the battery-related parameter is a battery voltage.

7. The method as claimed in claim 1, wherein the battery-related parameter is the number of hours that the battery (15) has been charged to obtain the current charge.

8. The method as claimed in claim 1, further comprising filtering the state of health obtained in step b), and using the filtered state of health in step c) to estimate the remaining driving distance.

9. A battery monitoring device (3) comprising:
processing circuitry (9), and
a storage medium (13),
wherein the storage medium (13) comprises a computer program which when executed by the processing circuitry causes (9) the battery monitoring device (3) to perform the method as claimed in claim 1.

10. The battery monitoring device (3) as claimed in claim 9, comprising an input device configured to obtain the measured battery-related parameter from an electrically powered mobility device (5), and an output device configured to send the remaining driving distance to the electrically powered mobility device (5).

11. An electrically powered mobility device (5) comprising a battery (15), a battery parameter measurement unit (23) configured to measure a battery-related parameter of the battery (15), and a communications unit (25) configured to send the measured battery-related parameter wirelessly to the battery monitoring device (3) as claimed in claim 9, and to receive the remaining driving distance from the battery monitoring device (3).

12. The electrically powered mobility device (5) as claimed in claim 11, comprising a display configured to display the remaining driving distance.

13. The electrically powered mobility device (5) as claimed in claim 11, wherein the electrically powered mobility device (5) is a wheelchair.

14. A system (1) comprising:
the electrically powered mobility device (5) as claimed in claim 11, and
a battery monitoring device (3) as claimed in claim 10 configured to communicate with the electrically powered mobility device (5).
